(19) United States
(12) Patent Application Publication
(10) Pub. No.: US 2010/0226171 A1
(43) Pub. Date: Sep. 9, 2010

(54) METHOD OF PROGRAMMING NONVOLATILE MEMORY DEVICE

(76) Inventor: Jung Chul HAN, Gyeonggi-do (KR)

Correspondence Address: IP & T Law Firm PLC, 7700 Little River Turnpike, Suite 207, Annandale, VA, 22003, US

(21) Appl. No.: 12/650,613

(22) Filed: Dec. 31, 2009

(30) Foreign Application Priority Data
Mar. 6, 2009 (KR) 10-2009-0019263

(51) Int. Cl. G11C 16/04; G11C 16/06

(52) U.S. Cl. 365/185.03; 365/185.19; 365/185.22

(57) ABSTRACT

A method of programming a nonvolatile memory device includes receiving a program command, performing program and verification operations in response to each of a number of program pulse, and performing an n number of program operations, where n is a positive integer and at least one verification operation for the n program operations has been omitted.

### CROSS-REFERENCE TO RELATED APPLICATIONS

Priority to Korean patent application number 10-2009-0019263 filed on Mar. 6, 2009, the entire disclosure of which is incorporated by reference herein, is claimed.

### BACKGROUND OF THE INVENTION

Exemplary embodiments of the present invention relate to a method of programming a nonvolatile memory device and, more particularly, to a method of programming a nonvolatile memory device, which is capable of narrowing the distribution of the threshold voltages by controlling program voltages and verification operations.

A nonvolatile memory device includes a memory cell array, a row decoder, a page buffer unit, etc. The memory cell array includes a plurality of word lines elongated in rows, a plurality of bit lines elongated in columns, and a plurality of cell strings corresponding to the respective bit lines.

The row decoder, coupled to string selection lines, word lines, and a common source line, is placed on one side of the memory cell array. Page buffers coupled to the plurality of bit lines are placed on the other side of the memory cell array.

Recently, to further increase the degree of integration of nonvolatile memory devices, active research is being done on a multi-bit cell which can store several data bits in a single memory cell. This type of a memory cell is called a multi-level cell (MLC). A memory cell capable of storing one bit is called a single level cell (SLC).

In the nonvolatile memory device, the number of latches for storing data when the data are sensed or programmed is gradually increasing.

Furthermore, in a nonvolatile memory device using MLCs, it is important to narrow the distribution of the threshold voltages of the cells. To control the distribution of the threshold voltages, a variety of operations, such as a double verification operation and a re-program operation, are being used, which increases the number of cases for performing a program operation.

FIG. 1 shows the distributions of the threshold voltages according to an MLC program operation.

FIG. 1 shows the distribution of the threshold voltages of MLCs each capable of storing three bits of data. The MLC capable of storing three bits of data logically performs first to third page programs on one word line.

When the first page program is performed on memory cells in an erased state, two respective distributions of threshold voltages for erase cells and programmed cells are produced. When the second page program is performed on the memory cells, the two distributions of the threshold voltages are increased to four distributions according to the states of the data.

Lastly, when the third page program is performed on the memory cells, the four distributions are increased to eight distributions.

It is important to narrow the width of a distribution of the threshold voltages of the memory cells while performing verification for the program operations on memory cells belonging to each distribution during the first to third page programs.

With an increase in the bit data to be stored, the number of distributions of the threshold voltages of memory cells is increased. With the number of distributions of the threshold voltages increasing, the interval between the distributions of the threshold voltages can be narrowed, resulting in deteriorated reliability of data.

That is, if the distribution of threshold voltages is widened because of an interference phenomenon, etc., neighboring distributions of the threshold voltages overlap each other, which results in a problem in that data are not correctly read in a read operation.

To solve the problem, it is important to narrow the width of a distribution of the threshold voltages. One of the representative methods is an increment step pulse program (ISPP) method of raising a program voltage by a predetermined step voltage increment when program operations are performed.

In the ISPP method, program and verification operations are alternately performed while raising a program voltage by a predetermined step voltage increment from a start voltage. Accordingly, the ISPP method is advantageous in that it can narrow the width of a distribution of the threshold voltages as compared with a method of performing a program operation using a single high program voltage.

If a program voltage supplied to the gates of memory cells having ideal characteristics is increased at regular intervals, the threshold voltages of the memory cells are increased at regular intervals.

Accordingly, if a program method using the ISPP method is performed on memory cells having ideal characteristics, the memory cells can have a distribution of threshold voltages having an ideally narrow width.

However, with a reduction in the size of a cell, there is a problem in that the threshold voltages of memory cells are irregularly increased because of various factors, such as the manufacturing process, an operation voltage, and temperature. That is, although a program voltage is raised by the same step voltage increments, the threshold voltages of the memory cells are not consistently increased, but rather are inconsistently increased. In general, the threshold voltages of memory cells are more inconsistently increased with an increase in the amount of bit information to be stored.

FIG. 2A is a graph showing that the program voltages of the ISPP method using regular step voltage increments and threshold voltages of memory cells being changed, and FIG. 2B shows a shift in the distributions of the threshold voltages.

As shown in FIG. 2A, if memory cells are programmed using program voltages on condition that a start program voltage is set to 15 V and subsequently raised in 1 V increments, the distribution of the threshold voltages of the memory cells is irregularly increased at an early stage, but, when the threshold voltages reach a certain voltage level, the distribution of the threshold voltages are regularly increased.

The same phenomenon occurs both in fast cells C1 having a fast program speed and in slow cells C2 having a slow program speed.

As shown in FIG. 2B, if memory cells, having an erased state and a first distribution 210 of the threshold voltages, are programmed, the first distribution 210 of the threshold voltages can become a third distribution 230 having a different width, without becoming a second distribution 220, because of a difference in the program speed of the memory cells.

### BRIEF SUMMARY OF THE INVENTION

One or more embodiments of the present invention relate to a method of programming a nonvolatile memory device, which is capable of narrowing the width of a distribution of the threshold voltages by controlling the step voltage increments of a program voltage and the number of verifications when memory cells are programmed.

A method of programming a nonvolatile memory device according to an embodiment of the present invention includes receiving a program command, performing program and verification operations in response to each program pulse of a plurality of program pulses, and performing an n number of program operations, wherein n is a positive integer and wherein at least one verification operation for the n program operations has been omitted.

Program voltages are raised by set step voltage increments in response to the program pulses.

In performing program and verification operations and performing an n number of program operations, the program pulses for initiating respective verification operations for first and second memory cell groups, each having threshold voltages shifted such that the threshold voltages belong to first or second distributions through the program operations, are differently set.

A voltage to which the distribution of the threshold voltages of the first memory cell group belongs is less than a voltage to which the distribution of the threshold voltages of the second memory cell group belongs.

A method of programming a nonvolatile memory device according to another embodiment of the present invention includes providing the nonvolatile memory device including first and second memory cell groups, each having threshold voltages shifted such that the threshold voltages belong to first or second distributions through program operations, supplying program voltages raised by step voltage increments in response to program pulses, and performing program and verification operations on the first memory cell group in response to each of the program pulses, and performing a k number of program operations on the second memory cell group, wherein at least one of verification operations for the k program operations has been omitted.

A method of programming a nonvolatile memory device according to yet another embodiment of the present invention includes receiving a program command, performing program and verification operations in response to each of a plurality of program pulses, and performing one verification operation whenever an n number of program operations have been performed and n is a natural number.

A method of programming a nonvolatile memory device according to further yet another embodiment of the present invention includes providing the nonvolatile memory device including first and second memory cell groups, each having threshold voltages shifted such that the threshold voltages belong to first or second distributions through program operations, supplying program voltages raised by step voltage increments in response to program pulses, performing program operations in response to the program pulses, performing program and verification operations on the first memory cell group up to an n number of program pulses, and performing a verification operation whenever a k^{th} program operation is performed from an n number of the program pulses, wherein n and k are natural numbers, and performing program and verification operations on the second memory cell group in response to all of the program pulses.

A voltage to which the distribution of the threshold voltages of the first memory cell group belongs is less than a voltage to which the distribution of the threshold voltages of the second memory cell group belongs.

### BRIEF DESCRIPTION OF THE DRAWINGS

FIG. 1 shows the distributions of the threshold voltages according to an MLC program operation;

FIG. 2A is a graph showing that the program voltages of an ISPP method using regular step voltage increments and showing that the threshold voltages of memory cells are changed;

FIG. 2B shows a shift in the distributions of the threshold voltages;

FIG. 3 is a block diagram of a nonvolatile memory device;

FIG. 4A shows the number of program operations using an ISPP method;

FIG. 4B shows the distributions of the threshold voltages of memory cells programmed using the ISPP method of FIG. 4A;

FIG. 5A is a diagram illustrating a program method according to a first embodiment of the present invention;

FIG. 5B shows the distributions of the threshold voltages of memory cells programmed using the program method of FIG. 5A;

FIG. 6A is a diagram illustrating a program method according to a second embodiment of the present invention;

FIG. 6B shows the distributions of the threshold voltages of memory cells programmed using the program method of FIG. 6A;

FIG. 7A is a diagram illustrating a program method according to a third embodiment of the present invention; and

FIG. 7B shows the distributions of the threshold voltages of memory cells programmed using the program method of FIG. 7A.

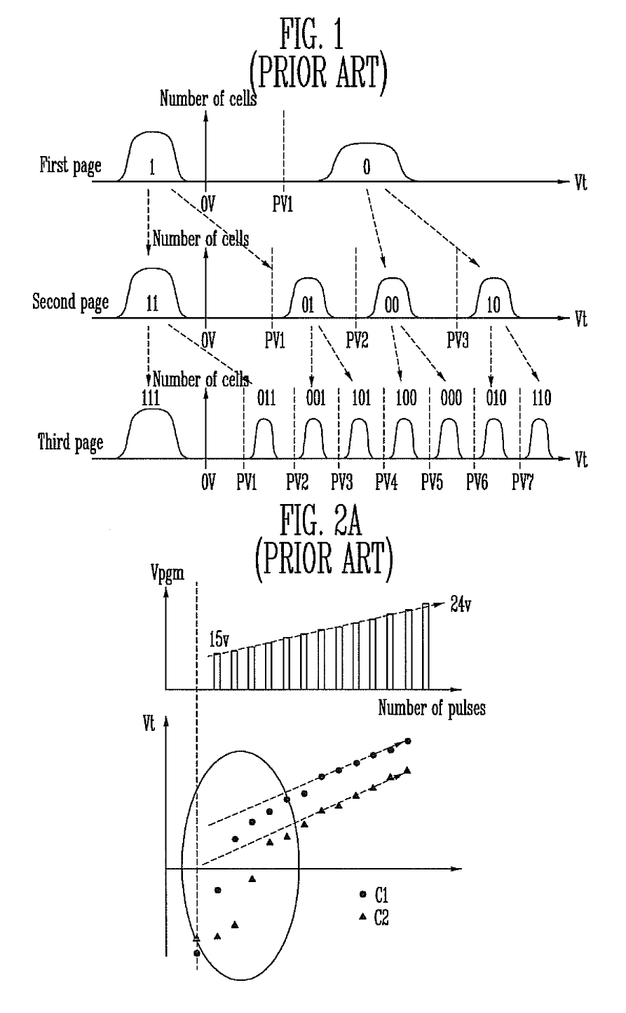

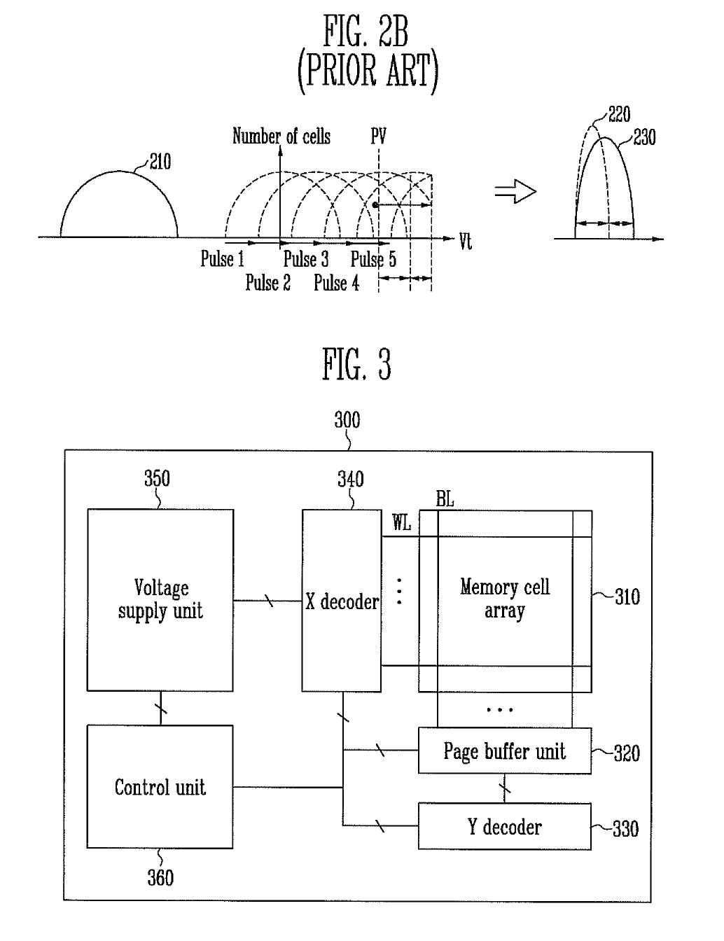

### DESCRIPTION OF THE INVENTION

Embodiments of the present invention are described in detail below with reference to the accompanying drawings. The drawing figures are provided to allow those having ordinary skill in the art to understand the scope of the embodiments of the present invention.

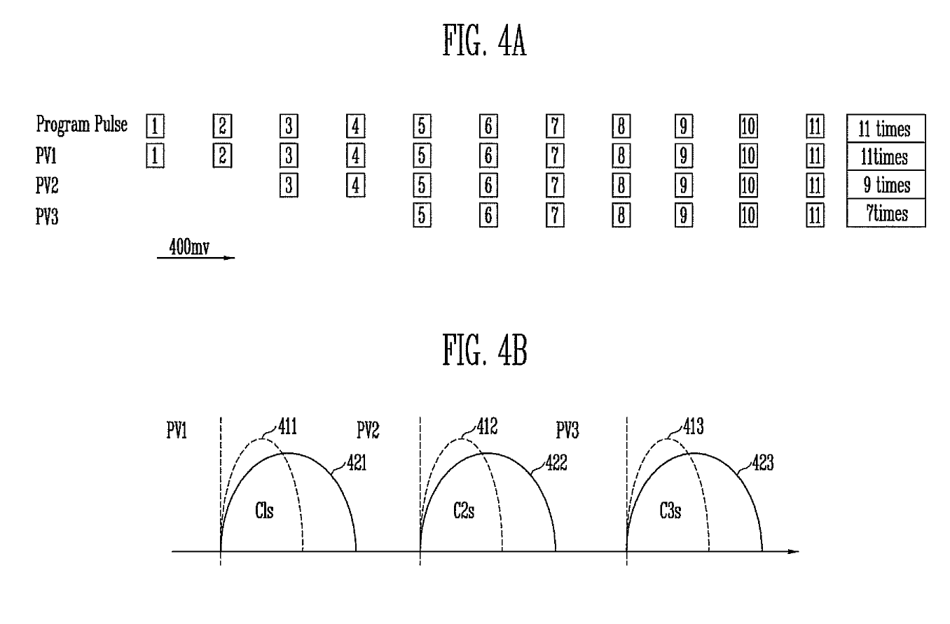

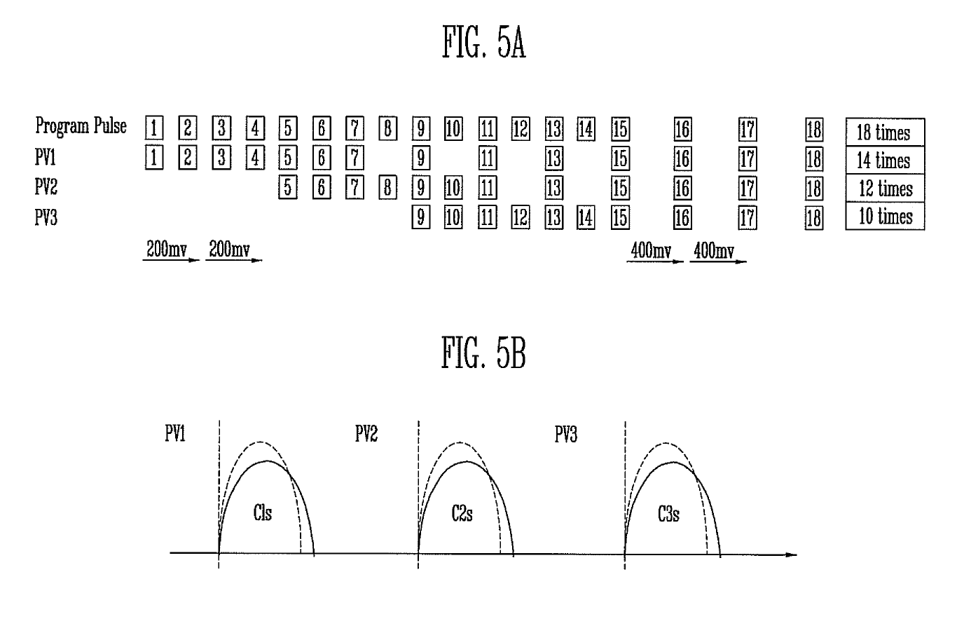

FIG. 3 is a block diagram of a nonvolatile memory device.

Referring to FIG. 3, the nonvolatile memory device 300 includes a memory cell array 310, a page buffer unit 320, a Y decoder 330, an X decoder 340, a voltage supply unit 350, and a control unit 360.

The memory cell array 310 includes memory cells for storing data. The memory cells are coupled to bit lines and word lines and are classified into several memory blocks.

The page buffer unit 320 includes a number of page buffers PB coupled to the bit lines. The page buffer PB is configured to latch data to be programmed into a selected memory cell or to store data read from a selected memory cell.

The Y decoder 330 is configured to provide a data 10 path to the page buffers PB. The X decoder 340 is configured to couple a global word line for providing operating voltages for program, erase, and read operations to the word lines of the memory cell array 310.

The voltage supply unit 350 is configured to generate the operating voltages supplied to the global word line. The control unit 360 is configured to control operations, such as the program, read, and erase operations of the nonvolatile memory device 300.

The control unit 360 is configured to control program voltages such that the program voltages are supplied according to the ISPP method when program operations are performed. Here, the control unit 360 differently sets step voltage increments according to the characteristics of memory cells and controls the number of verification operations.

FIG. 4A shows the number of program operations using the ISPP method.

FIG. 4A shows a case in which, when program voltages are supplied, step voltage increments are regularly raised by 400 mV. Here, verification operations using second and third verification voltages PV2 and PV3 are not initially performed. The verification operations using the second and third verification voltages PV2 and PV3 are performed only when at least a preset number of program pulses have been supplied.

This is because, when a program operation is first performed, a probability that the threshold voltage of a memory cell may become more than the second or third verification voltage PV2 or PV3 is low. Accordingly, the number of verifications is set such that the verification operations using the second and third verification voltages PV2 and PV3 are performed after at least a preset number of program operations have been performed.

Accordingly, when the program pulse is supplied 11 times, the number of program operations is 11, the number of verifications using the first verification voltage PV1 is 11, and the number of verifications using the second verification voltage PV2 is 9. Further, the number of verifications using the third verification voltage PV3 is 7.

The distributions of the threshold voltages, obtained according to the ISPP method of FIG. 4A, are shown in FIG. 4B.

FIG. 4B shows the distributions of the threshold voltages of memory cells programmed using the ISPP method of FIG. 4A.

Referring to FIG. 4B, memory cells having ideal characteristics have distributions of the threshold voltage, such as the first to third distributions 411 to 413. In reality, however, the memory cells have distributions of the threshold voltages, each having a wide width, such as the fourth to sixth distributions 421 to 423.

To solve this problem, in a first embodiment of the present invention, the ISPP method can be performed by differently setting step voltage increments.

FIG. 5A is a diagram illustrating a program method according to a first embodiment of the present invention.

Referring to FIG. 5A, in the program method according to the first embodiment of the present invention, a step voltage increment is set to 200 mV up to a preset number of program pulses and is subsequently set to 400 mV.

Assuming that first to eighteenth program pulses are supplied as shown in FIG. 5A, a program voltage is raised by 200 mV increments in response to the first to fourteenth program pulses. The program voltage is raised by 400 mV increments in response to subsequent program pulses.

In this case, when the distributions of the threshold voltages are classified on the basis of the first to third verification voltages PV1 to PV3, memory cells programmed to have threshold voltages between the first verification voltage PV1 and the second verification voltage PV2 are called a first memory cell group C1s, memory cells programmed to have threshold voltages between the second verification voltage PV2 and the third verification voltage PV3 are called a second memory cell group C2s, and memory cells programmed to have threshold voltages between the second verification voltage PV2 and the third verification voltage PV3 are called a third memory cell group C3s.

Furthermore, different step voltage increments are set with respect to the first to third memory cell groups C1s to C3s.

In other words, when the first verification operation using the first verification voltage PV1 is performed on the first memory cell group C1s, the first verification operation is performed in response to each of the first to seventh program pulses, and the first verification operation is subsequently performed in response to only odd-numbered program pulses.

Accordingly, the first verification operation is omitted in the program operation in response to the eighth, tenth, twelfth, and fourteenth program pulses. By controlling whether the verification operation will be performed as described above, the program voltage for the first memory cell group C1s is raised by 200 mV increments up to the seventh program pulse and, subsequently, the program voltage therefore is raised by 400 mV increments.

In a similar way, when the second verification operation using the second verification voltage PV2 is performed on the second memory cell group C2s, a verification operation is started from the fifth program pulse, and the second verification operation is performed in response to each program pulse up to the eleventh program pulse. After the eleventh program pulse, the second verification operation is performed in response to only odd-numbered program pulses. The reason why the second verification operation is started from the fifth program pulse is that, in order to reduce the time that it takes to perform programs, verification operations are set to be performed after a preset number of program pulses with respect to a high verification voltage. Accordingly, the program voltage for the second memory cell group C2s is raised by 200 mV increments up to the eleventh program pulse and, subsequently, the program voltage therefore is raised by 400 mV increments.

Furthermore, when the third verification operation using the third verification voltage PV3 is performed on the third memory cell group C3s, a verification operation is started from the ninth program pulse, and the third verification operation is performed in response to each program pulse. Accordingly, the program voltage for the third memory cell group C3s is raised by 200 mV increments up to the fifteenth program pulse and, subsequently, the program voltage therefore is raised by 400 mV increments.

According to the above program method, the program pulse must be supplied 18 times. Furthermore, the first verification operation is performed 14 times, the second verification operation is performed 12 times, and the third verification operation is performed 10 times. In addition, when the start program voltage is 15 V, the highest program voltage becomes 19.2 V.

The distributions of the threshold voltages of the memory cells, obtained as a result of performing the program operation using varying step voltage increments according to the degree of programs as described above, are shown in FIG. 5B.

FIG. 5B shows the distributions of the threshold voltages of memory cells programmed using the program method of FIG. 5A.

From FIG. 5B, it can be seen that the width of each of the distributions of the threshold voltages has been narrowed as compared with FIG. 4B. The reason why the width of each of the distributions of the threshold voltages has been narrowed is described as follows. At an early stage, the distribution of the threshold voltages of memory cells is irregularly changed in response to a program pulse due to the characteristics of the memory cells. For this reason, the width of a step voltage increment of a program voltage is set to be small such that the threshold voltages are regularly raised. Accordingly, the width of a distribution of the threshold voltages of memory cells that are irregularly programmed can be narrowed.

A program method according to a second embodiment of the present invention is described below.

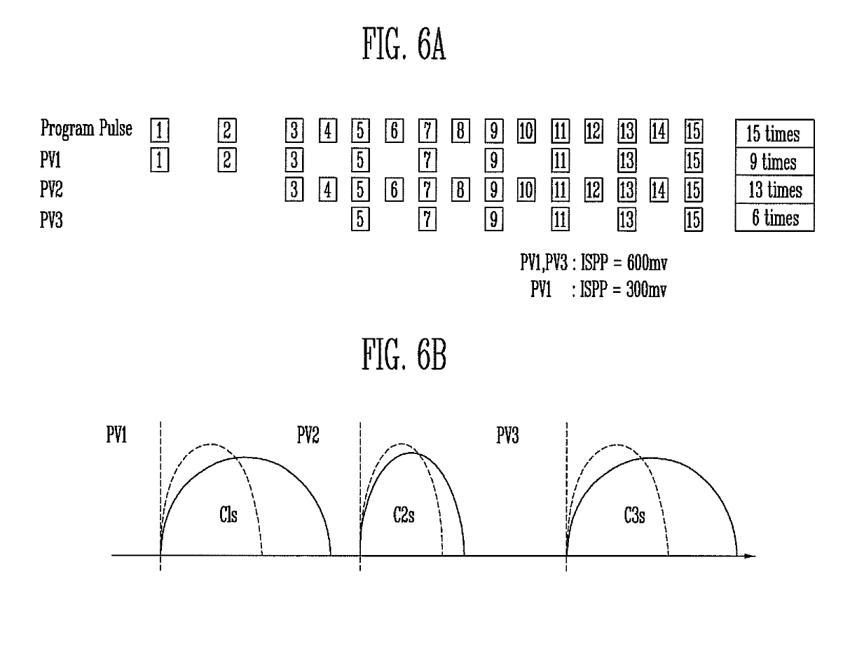

FIG. 6A is a diagram illustrating a program method according to the second embodiment of the present invention.

In the program method according to the second embodiment of the present invention, step voltage increments are differently set according to distributions of the threshold voltages of memory cells to be programmed.

That is, a step voltage increment for the first and third memory cell groups C1s and C3s is set to 600 mV, and a step voltage increment for the second memory cell group C2s is set to 300 mV.

In the method of setting different step voltage increments for the memory cell groups, verification operations can be omitted as in the first embodiment of the present invention.

That is, a program voltage increment is raised by 600 mV in response to the first to third program pulses, and a program voltage increment is raised by 300 mV in response to the fourth to fifteenth program pulses.

The first verification operation is performed on the first memory cell group C1s in response to only odd-numbered program pulses. The second verification operation is performed on the second memory cell group C2s in response to each of the third to fifteenth program pulses. Furthermore, the third verification operation is performed on the third memory cell group C3s in response to only odd-numbered program pulses from the fifth program pulse.

When the verification operations are controlled as described above, the program voltage for the first and third memory cell groups C1s and C3s can be raised by 600 mV, and the program voltage for the second memory cell group C2s can be raised by 300 mV. Of course, the program voltage for the second memory cell group C2s is raised by 600 mV until the first to third program pulses are supplied.

When the program operation is performed as in the second embodiment of the present invention, the program pulse is supplied 15 times, the first verification operation is performed 9 times, the second verification operation is performed 13 times, and the third verification operation is performed 6 times. Assuming that a start program voltage is 15 V, the highest program voltage becomes 19.8 V.

When the program operation is performed according to the second embodiment of the present invention, the distributions of the threshold voltage, such as that shown in FIG. 6B, are produced.

FIG. 6B shows the distributions of the threshold voltages of the memory cells programmed using the program method of FIG. 6A.

From FIG. 6B, it can be seen that the width of the distribution of the threshold voltages of the second memory cell group C2s is narrower than that of each of the first and third memory cell groups C1s and C3s.

If the distributions of the threshold voltages, such as that shown in FIG. 6B, are produced, a margin between the distributions of the threshold voltages of the first to third memory cell groups C1s to C3s is increased. Accordingly, reliability when data are read can be secured.

If the program operation is performed as in the first and second embodiments, all the widths of the distributions of the threshold voltages are narrowed in the first embodiment, but the number of program pulses and the number of verifications can be increased. Consequently, the time that it takes to perform the program operation can be increased.

Furthermore, if the program operation is performed as in the second embodiment, the width of the distributions of the threshold voltages of only the second memory cell group C2s is narrowed. Although a read margin of the second embodiment is smaller than that of the first embodiment, some degree of a read margin can be secured. Furthermore, the time that it takes to perform the program operation can be reduced as compared with the first embodiment.

To reduce the program time and improve reliability, a program operation can be performed as in the following third embodiment in which the methods of the first and second embodiments are mixed.

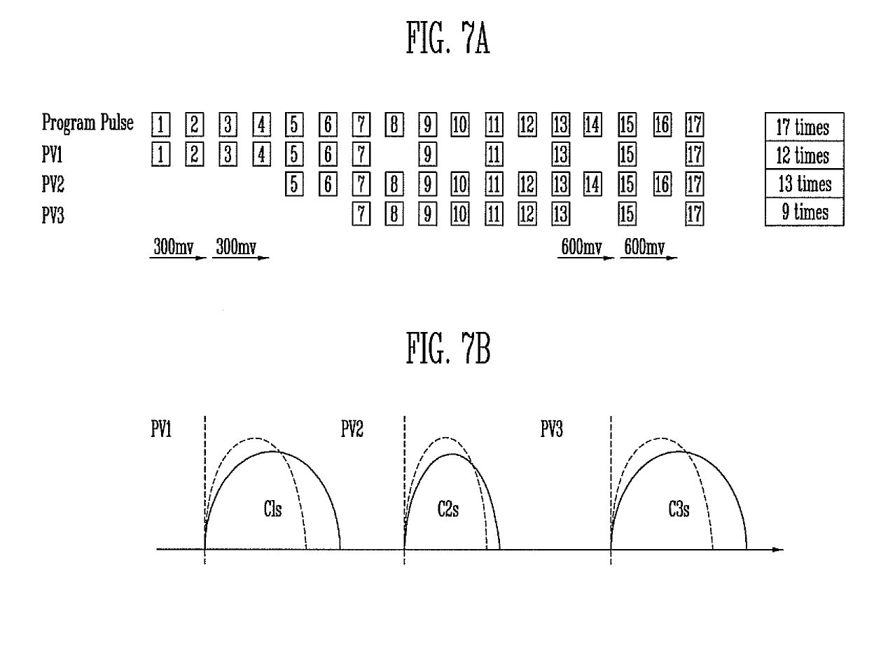

FIG. 7A is a diagram illustrating a program method according to the third embodiment.

Referring to FIG. 7A, in the program method according to the third embodiment of the present invention, a step voltage increment is basically set to 300 mV. Further, some verification operations are omitted in order to set different step voltage increments for the first to third memory cell groups C1s to C3s.

At an early stage, a program voltage raised by 300 mV increments is supplied to the first and third memory cell groups C1s, C3s. After some program pulses have been supplied, the program voltage for the first and third memory cell groups C1s and C3s is raised by 600 mV. Furthermore, a program voltage for the second memory cell group C2s is raised by 300 mV.

To this end, the first verification operation using the first verification voltage PV1 is performed on the first memory cell group C1s in response to each of the first to seventh program pulses. Subsequently, the first verification operation is performed on the first memory cell group C1s in response to only odd-numbered program pulses.

Next, the second verification operation using the second verification voltage PV2 is first performed on the second memory cell group C2s in response to the fifth program pulse and then performed in response to each of the sixth to seventeenth program pulses.

Next, the third verification operation using the third verification voltage PV3 is first performed on the third memory cell group C3s in response to the seventh program pulse, performed in response to each of the eighth to thirteenth program pulses, and then performed in response to only odd-numbered program pulses.

If the step voltage increments and the verification operations are controlled as in the third embodiment, the program pulse is supplied 17 times, the first verification operation is performed 12 times, the second verification operation is performed 13 times, and the third verification operation is performed 9 times.

The distributions of the threshold voltages, obtained as a result of performing the program operation according to the third embodiment, are shown in FIG. 7B.

FIG. 7B shows the distributions of the threshold voltages of memory cells programmed using the program method of FIG. 7A.

From FIG. 7B, it can be seen that the distribution of the threshold voltages of the second memory cell group C2s has the narrowest width and the distributions of the threshold voltages of the first and third memory cell groups C1s and C3s also have a narrowed width.

The results of performing the program methods according to the first to third embodiments are compared and described below.

In the first embodiment, although the widths of the distributions of the threshold voltages of all of the first to third memory cell groups C1s to C3s are narrowed, the number of programs and the number of verifications are the largest as compared with the second and third embodiments. Accordingly, the time that it takes to perform the program operation is the longest.

In the second embodiment, the width of the distribution of the threshold voltages of the second memory cell group C2s is the narrowest, and the number of programs and the number of verifications that are performed are the smallest. Accordingly, the time that it takes to perform the program operation is the shortest.

In the third embodiment combining the first and second embodiments, the width of the distribution of the threshold voltages of the second memory cell group C2s is the narrowest, and the widths of the distributions of the threshold voltages of the first and third memory cell groups C1s and C3s are narrowed to some extent. Accordingly, the third embodiment has the largest read margin. Further, the number of programs and the number of verifications are more than those of the second embodiment, but less than those of the first embodiment. Accordingly, the time that it takes to perform a program operation can be reduced as compared with the first embodiment.

Furthermore, when comparing the case in which the step voltage increment of a program voltage is set to 200 mV and 400 mV and the case in which the step voltage increment is set to 300 mV and 600 mV, a value in which all of the widths of the distributions of the threshold voltages of the first to third memory cell groups C1s to C3s are added is similar, but the number of program pulses and the number of verifications are reduced in the case in which the step voltage increment is set to 300 mV and 600 mV.

As described above, the step voltage increment of a program voltage is controlled according to the state of data to be stored in a memory cell, and the number of verifications is controlled according to the level of a verification voltage. Accordingly, a margin between the distributions of the threshold voltages of memory cells can be widened, and reliability of data can be increased.

Further, step voltages used when memory cells are programmed are irregularly set, and the number of verifications performed on the memory cells is controlled. Accordingly, the width of the distribution of the threshold voltages of the memory cells can be narrowed, leading to improved reliability of data.

What is claimed is:

1. A method of programming a nonvolatile memory device, comprising:
receiving a program command;
performing program and verification operations in response to each program pulse of a plurality of program pulses; and
performing an n number of program operations, wherein n is a positive integer and wherein at least one verification operation for the n program operations has been omitted.

2. The method of claim 1, wherein program voltages are raised by set step voltage increments in response to the program pulses.

3. The method of claim 1, wherein in performing program and verification operations and performing an n number of program operations, the program pulses for initiating respective verification operations for first and second memory cell groups, each having threshold voltages shifted such that the threshold voltages belong to first or second distributions through these program operations, are differently set.

4. The method of claim 1, wherein a voltage to which the distribution of the threshold voltages of the first memory cell group belongs is less than a voltage to which the distribution of the threshold voltages of the second memory cell group belongs.

5. A method of programming a nonvolatile memory device, comprising:
providing the nonvolatile memory device including first and second memory cell groups, each having threshold voltages shifted such that the threshold voltages belong to first or second distributions through program operations;
supplying program voltages raised by step voltage increments in response to program pulses; and
performing program and verification operations on the first memory cell group in response to each of the program pulses, and performing a k number of program operations on the second memory cell group, wherein at least one verification operation for the k program operations has been omitted.

6. A method of programming a nonvolatile memory device, comprising:
receiving a program command;
performing program and verification operations in response to each of a plurality of program pulses; and
performing one verification operation whenever an n number of program operations have been performed and n is a natural number.

7. A method of programming a nonvolatile memory device, comprising:
providing the nonvolatile memory device including first and second memory cell groups, each having threshold voltages shifted such that the threshold voltages belong to first or second distributions through program operations;
supplying program voltages raised by step voltage increments in response to program pulses;
performing program operations in response to the program pulses;
performing program and verification operations on the first memory cell group up to an n number of program pulses, and performing a verification operation whenever a k^{th} program operation has been performed from an n number of program pulses, wherein n and k are natural numbers; and
performing program and verification operations on the second memory cell group in response to all of the program pulses.

8. The method of claim 7, wherein a voltage to which the distribution of the threshold voltages of the first memory cell group belongs is less than a voltage to which the distribution of the threshold voltages of the second memory cell group belongs.
